(19) United States
(12) Patent Application Publication
(10) Pub. No.: US 2020/0043790 A1
(43) Pub. Date: Feb. 6, 2020

(54) SYSTEMS AND METHODS FOR FABRICATING SEMICONDUCTOR DEVICES VIA REMOTE EPITAXY

(71) Applicant: Massachusetts Institute of Technology, Cambridge, MA (US)

(72) Inventors: Kyusang Lee, Crozet, VA (US); Jeehwan Kim, Cambridge, MA (US)

(73) Assignee: Massachusetts Institute of Technology, Cambridge, MA (US)

(21) Appl. No.: 16/605,897

(22) PCT Filed: Apr. 18, 2018
(86) PCT No.: PCT/US2018/028089

§ 371 Date: Oct. 17, 2019

Related U.S. Application Data
(60) Provisional application No. 62/487,739, filed on Apr. 20, 2017.
(60) Provisional application No. 62/487,036, filed on Apr. 19, 2017.
(60) Provisional application No. 62/486,518, filed on Apr. 18, 2017.

(51) Int. Cl. H01L 21/78; H01L 21/02; H01L 21/306

(52) U.S. Cl. CPC H01L 21/7813; H01L 21/02463; H01L 21/30604; H01L 21/02546; H01L 21/02502

(57) ABSTRACT

A method of manufacturing a semiconductor device includes forming a release layer on a first substrate and the release layer includes a planar organic molecule. The method also includes forming a single-crystalline film on the release layer and transferring the single-crystalline film from the release layer to a second substrate.

### CROSS-REFERENCES TO RELATED APPLICATIONS

This application claims the priority benefit under 35 U.S.C. § 119(e) of U.S. Application No. 62/486,518, filed Apr. 18, 2017, entitled “TWO-DIMENSIONAL MATERIAL BASED LAYER TRANSFER ASSISTED BY CHEMICAL REACTION,” which is hereby incorporated herein by reference in its entirety.

This application also claims the priority benefit under 35 U.S.C. § 119(e) of U.S. Application No. 62/487,036, filed Apr. 19, 2017, entitled “REMOTE EPITAXY THROUGH PLANAR ORGANIC MONOLAYER,” which is hereby incorporated herein by reference in its entirety.

This application claims the priority benefit under 35 U.S.C. § 119(e) of U.S. Application No. 62/487,739, filed Apr. 20, 2017, entitled “FABRICATION OF LOW-COST COMPOUND SEMICONDUCTOR DEVICES VIA REMOTE EPITAXY AND TWO-DIMENSIONAL LAYER TRANSFER,” which is hereby incorporated herein by reference in its entirety.

### BACKGROUND

In advanced electronic and photonic technologies, devices are usually fabricated from functional semiconductors, such as III-N semiconductors, III-V semiconductors, II-VI semiconductors, and Ge. The lattice constants of these functional semiconductors typically do not match the lattice constants of silicon substrates. As understood in the art, lattice constant mismatch between a substrate and an epitaxial layer on the substrate can introduce strain into the epitaxial layer, thereby preventing epitaxial growth of thicker layers without defects. Therefore, non-silicon substrates are usually employed as seeds for epitaxial growth of most functional semiconductors. However, non-Si substrates with lattice constants matching those of functional materials can be costly and therefore limit the development of non-Si electronic/photonic devices.

One method of addressing the high cost of non-silicon substrates is the “layer-transfer” technique, in which functional device layers are grown on lattice-matched substrates and then removed and transferred to other substrates. The remaining lattice-matched substrates can then be reused to fabricate another device layer, thereby reducing the cost. However, existing layer-transfer techniques, such as chemical lift-off, optical lift-off, and controlled spalling, usually suffer from one or more drawbacks. For example, chemical lift-off is usually slow and tends to contaminate the surface of the growth substrate, thereby rendering it challenging to reuse the growth substrate. Optical lift-off also reduces the reusability of the growth substrate (e.g., to less than 5 times of reuse) because the optical beams employed to remove the device layer are also likely to damage the surface of the growth substrate. Controlled spalling usually has a higher throughput compared to chemical/optical lift-off, but it can be challenging to precisely remove the entire device layer from the growth substrate.

### SUMMARY

Embodiments of the present invention include apparatus, systems, and methods for fabricating semiconductor devices via remote epitaxy. In one example, a method of manufacturing a semiconductor device includes forming a release layer on a first substrate and the release layer includes a planar organic molecule. The method also includes forming a single-crystalline film on the release layer and transferring the single-crystalline film from the release layer to a second substrate.

In another example, a method of semiconductor processing includes depositing, via evaporation, a planar organic molecule on a first substrate to form a release layer having a thickness substantially equal to or less than 2 nm. The method also includes forming a first capping layer on the release layer at a first temperature. The first capping layer includes a semiconductor and has a thickness of about 5 nm to about 10 nm. The method also includes epitaxially growing a first single-crystalline film on the first capping layer at a second temperature greater than the first temperature and the first single-crystalline film also includes the semiconductor. The method further includes transferring the first single-crystalline film from the release layer to a second substrate, followed by forming a second capping layer on the release layer and forming a second single-crystalline film on the second capping layer.

In yet another example, a method of semiconductor processing includes forming a release layer on a first substrate and forming a sacrificial layer on the release layer. The method also includes forming a single-crystalline film on the release layer and etching away the sacrificial layer so as to release the single-crystalline film from the first substrate. The method also includes transferring the single-crystalline film from the first substrate to a second substrate.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIGS. 1A-1D illustrate a method of fabricating a semiconductor device via remote epitaxy.

FIGS. 2A-2B illustrate a method of fabricating semiconductor devices using an organic release layer.

FIGS. 3A-3D show molecular structures of planar organic molecules that can be used for the release layer in the method illustrated in FIGS. 2A-2B.

FIGS. 4A-4C illustrate formation of an ordered planar organic layer that can be used in the method illustrated in FIGS. 2A-2B.

FIGS. 5A-5C illustrate a method of fabricating semiconductor devices using a capping layer to protect the release layer.

FIGS. 6A-6B illustrate a method of transferring an epitaxial layer from an organic release layer using a stressor layer.

FIGS. 7A-7B illustrate a method of transferring an epitaxial layer by etching away the organic release layer.

FIGS. 8A-8D illustrate a method of fabricating semiconductor devices using a release layer and a sacrificial layer.

FIGS. 9A-9D illustrate a method of fabricating semiconductor devices using a patterned release layer and a sacrificial layer.

### DETAILED DESCRIPTION

### Overview

To address the drawbacks in conventional layer-transfer methods, systems and methods described herein employ a remote epitaxy technique to fabricate semiconductor devices. In this technique, a device layer (also referred to as a functional layer) is epitaxially grown on a release layer, which in turn is disposed on a substrate (also referred to as a growth substrate) that is lattice-matched to the device layer. As used herein, lattice-matching refers to situations in which two lattice constants are different by less than 10% (e.g., about 10%, about 9%, about 8%, about 7%, about 6%, about 5%, about 4%, about 3%, about 2%, about 1%, or less, including any values and sub ranges in between). The release layer is made of a two-dimensional (2D) material to support van der Waals epitaxy (VDWE), in which the device layer has only van der Waals interactions with the underneath release layer. As understood in the art, a van der Waals interaction is not a chemical bond between two materials. Instead, it originates from the dipole interactions between atoms. Compared to ionic or covalent bonding, the van der Waals force is much weaker. As a result, when the device layer is deposited on the release layer, the device layer grows unstrained and forms a lattice having the lattice constant that is identical to its bulk lattice constant.

In remote epitaxy, the epitaxial registry of adatoms can be remotely assigned by the underlying growth substrate via modulating the distance between the growth substrate and the device layer (also referred to as the interaction gap). In other words, the growth substrate, although physically separated from the device layer by the release layer, still has a significant orienting effect on the device layer during epitaxial growth because the release layer is so thin. The grown device layer can then be readily released from the release layer, thereby allowing multiple reuses of the growth substrate.

The atomically thin release layer in remote epitaxy can be constructed from various materials. For example, the release layer can include a graphene monolayer. In another example, the release layer can include planer organic molecules, which can be deposited via evaporation techniques that can be more cost effective than the graphene fabrication process. Any other appropriate 2D material can also be used.

The layer transfer after remote epitaxy takes advantage of the weak interaction between the device layer and the 2D material interface on the release layer. A sacrificial layer can be formed between the release layer and the device layer to enhance this layer transfer process. After the remote epitaxy, the sacrificial layer can be selectively etched away, leaving the device layer separated from the release layer. Accordingly, the device layer can be more readily transferred away to another substrate for further processing.

Methods of Fabricating Semiconductor Devices Via Remote Epitaxy

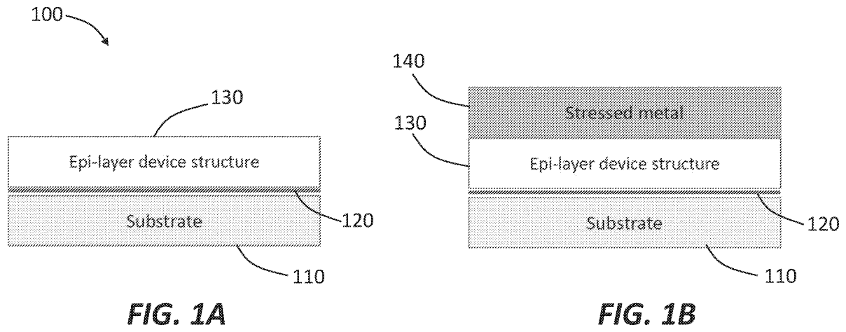

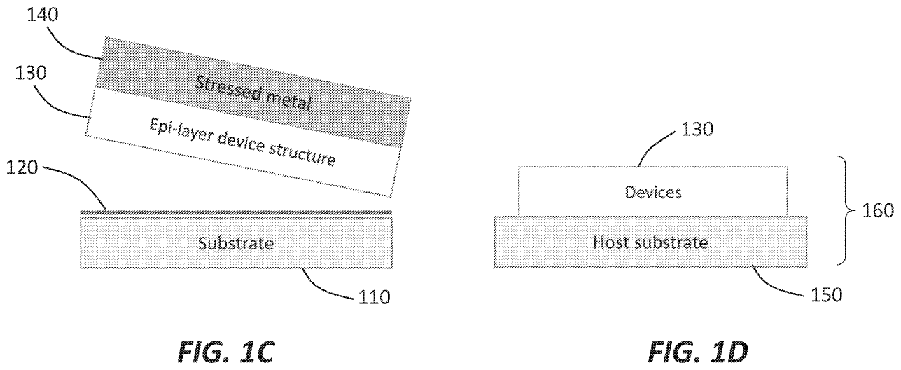

FIGS. 1A-1D illustrate a method 100 of fabricating a semiconductor device via remote epitaxy. The method 100 includes forming an epitaxial layer 130 (also referred to as a device layer 130, an epilayer 130, or a functional layer 130) on a release layer 120, which is disposed on a growth substrate 110, as illustrated in FIG. 1A. The growth substrate 110 is usually in crystalline form and has a first lattice constant. The release layer 120 includes a 2D material such that the interaction between the release layer 120 and the epitaxial layer 130 is dominated by van der Waals forces. In addition, the thickness of the release layer 120 is less than a threshold value (e.g., about 1 nm or less) so as to allow the field of the growth substrate 110 to guide the epitaxial growth of the epitaxial layer 130. Therefore, the epitaxial layer 130 usually includes a single-crystalline film having a second lattice constant substantially equal to the first lattice constant. However, polycrystalline or amorphous films can also be fabricated.

FIG. 1B shows that a stressor 140 is disposed on the epitaxial layer 130. For example, the stressor 140 can include a high-stress metal film, such as a Ni film. In this example, the Ni stressor 140 can be deposited on the epitaxial layer 130 in an evaporator at a vacuum level of 1×10⁻⁵ Torr. An optional tape layer can be disposed on the stressor 140 to facilitate handling of the stressor 140 and the epitaxial layer 130. The tape and the stressor 140 can be used to mechanically exfoliate the epitaxial layer 130 from the release layer 120 by applying high strain energy to the interface between the epitaxial layer 130 and the release layer 120, as illustrated in FIG. 1C. The release rate can be fast at least due to the weak van der Waals bonding between the 2D material in the release layer 120 and other materials in the epitaxial layer 130.

In FIG. 1D, the released epitaxial layer 130 is disposed on a host substrate 150 to form a semiconductor device 160. Further processing of the semiconductor device 160 can include, for example, etching, deposition, and bonding. After the epitaxial layer 130 is placed on the host substrate 150, the stressor 140 can be removed by, for example, etching with a FeCl₃-based solution.

In the method 100, after the release of the epitaxial layer 130 shown in FIG. 1C, the remaining platform including the growth substrate 110 and the release layer 120 can be reused for next cycle of epilayer fabrication. Alternatively, the release layer 120 can also be removed. In this case, a new release layer can be disposed on the growth substrate 110 before next cycle of epilayer fabrication. In either case, the release layer 120 can protect the growth substrate 110 from damage, thereby allowing multiple uses of the growth substrate 110 and reducing the cost of fabricating the semiconductor device 160.

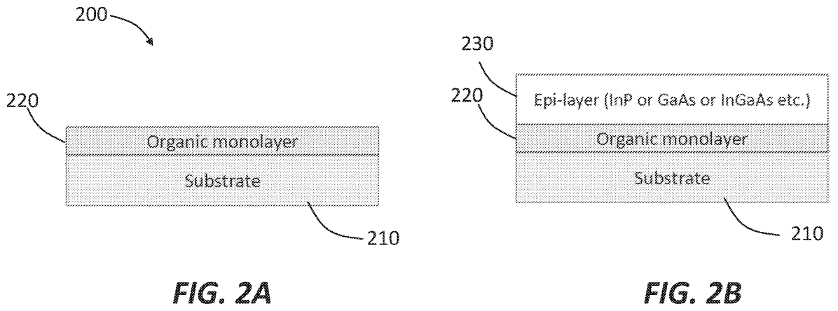

Various types of 2D materials can be used for the release layer 120. In one example, the release layer 120 includes graphene (e.g., monolayer graphene or multilayer graphene). In another example, the release layer 120 includes transition metal dichalcogenide (TMD) monolayers, which are atomically thin semiconductors of the type MX₂, with M being a transition metal atom (e.g., Mo, W, etc.) and X being a chalcogen atom (e.g., S, Se, or Te). In a TMD lattice, one layer of M atoms is usually sandwiched between two layers of X atoms. In yet another example, the release layer 120 can include a single-atom layer of metal, such as silver, palladium, and rhodium. In yet another example, the release layer 120 can include planar organic molecules (more details are provided below with reference to FIGS. 2A-8B below).

In one example, the release layer 120 can be directly fabricated on the growth substrate 110. For example, the release layer 120 can include planar organic molecules that can be deposited on the growth substrate 110 via evaporation. In another example, the release layer 120 can be prepared on another substrate and then transferred to the growth substrate 110. For example, the release layer 120 can include graphene and can be formed on a silicon carbide substrate before being transferred to the growth substrate 110.

When graphene is used, the release layer 120 can be prepared via various methods. In one example, the release layer 120 can include epitaxial graphene grown on a (0001) 4H-SiC wafer with a silicon surface. The fabrication of the release layer 120 can include a multistep annealing process. A first annealing step can be performed in H₂ gas for surface etching, and a second annealing step can be performed in Ar for graphitization at high temperature (e.g., about 1,575° C.). In another example, the release layer 120 can be grown on a substrate via a chemical vapor deposition (CVD) process. The substrate can include a nickel substrate or a copper substrate. Alternatively, the substrate can include an insulating substrate of SiO₂, HfO₂, Al₂O₃, Si₃N₄, and practically any other high temperature compatible planar material by CVD.

Various methods can also be used to transfer the graphene release layer 120 to the growth substrate 110. In one example, a carrier film can be attached to the graphene release layer 120. The carrier film can include a thick film of Poly(methyl methacrylate) (PMMA) or a thermal release tape and the attachment can be achieved via a spin-coating process. After the combination of the carrier film and the graphene release layer 120 is disposed on the growth substrate 110, the carrier film can be dissolved (e.g., in acetone) for further fabrication of the epitaxial layer 130 on the graphene release layer 120.

In another example, a stamp layer including an elastomeric material, such as polydimethylsiloxane (PDMS), can be attached to the graphene release layer 120. The substrate for growing graphene can be etched away, leaving the combination of the stamp layer and the graphene release layer 120. After the stamp layer and the graphene release layer 120 are placed on the growth substrate 110, the stamp layer can be removed by mechanical detachment, producing a clean surface of the graphene release layer 120 for further processing.

In yet another example, a self-release transfer method can be used to transfer the graphene release layer 120 to the growth substrate 110. In this method, a self-release layer is first spun-cast over the graphene release layer 120. An elastomeric stamp is then placed in conformal contact with the self-release layer. The substrate for growing graphene can be etched away to leave the combination of the stamp layer, the self-release layer, and the graphene release layer 120. After this combination is placed on the growth substrate 110, the stamp layer can be removed mechanically and the self-release layer can be dissolved under mild conditions in a suitable solvent. The self-release layer can include polystyrene (PS), poly(isobutylene) (PM) and Teflon AF (poly[4,5-difluoro-2,2-bis(trifluoromethyl)-1,3-dioxole-co-tetrafluoroethylene]). More details of using graphene in the release layer 120 can be found in PCT Publication No. WO 2017/044577, filed Sep. 8, 2016, entitled “SYSTEMS AND METHODS FOR GRAPHENE BASED LAYER TRANSFER,” which is hereby incorporated herein by reference in its entirety.

The fabrication of the epitaxial layer 130 can be carried out using any suitable semiconductor fabrication technique known in the art. For example, low-pressure Metal-Organic Chemical Vapor Deposition (MOCVD) can be used to grow the epitaxial layer 130 (e.g., a GaN film) on the release layer 120. In this example, the release layer 120 and the growth substrate 110 can be baked (e.g., under H₂ for >15 min at >1,100° C.) to clean the surface. Then the deposition of the epitaxial layer 130 including GaN can be performed at, for example, 200 mbar. Trimethylgallium, ammonia, and hydrogen can be used as the Ga source, nitrogen source, and carrier gas, respectively. A modified two-step growth can be employed to obtain flat GaN epitaxial films on the release layer 120. The first step can be carried out at a growth temperature of 1,100° C. for few minutes where guided nucleation at terrace edges can be promoted. The second growth step can be carried out at an elevated temperature of 1,250° C. to promote the lateral growth. Vertical GaN growth rate in this case can be around 20 nm per min.

In one example, the epitaxial layer 130 includes a 2D material system. In another example, the epitaxial layer 130 includes a 3D material system. The flexibility to fabricate both 2D and 3D material systems allows fabrication of a wide range of optical, opto-electronic, thermoelectric, and photonic devices known in the art.

For example, the epitaxial layer 130 can include GaAs, which can be used for fabricating solar cells (e.g., thin film solar cells), lasers (e.g., near-infrared laser diode, or double heterostructure lasers), light emitting diodes (LEDs, such as red LEDs), detectors (e.g., for near infrared detection and x-ray detection), and thermometers (e.g., fiber optic thermometers). The epitaxial layer 130 including GaAs can also be used to fabricate various types of transistors, such as metal-semiconductor field-effect transistors (MESFETs), high electron mobility transistors (HEMTs, including pHEMTs, mHEMTs, and induced HEMTs), junction field effect transistors (JFETs), and heterojunction bipolar transistors (HBTs).

In another example, the epitaxial layer 130 can include InGaAs, which can be used for fabricating detectors, such as infrared detectors, avalanche photodiodes, integrated photodiodes, and focal plane arrays. The epitaxial layer 130 including InGaAs can also be used to fabricate transistors (e.g., HEMTs) and solar cells (e.g., triple-junction solar cells).

Furthermore, thermoelectric devices can also be constructed from the epitaxial layer 130 including InGaAs. These devices include energy harvesting devices, such as thin-film thermophotovoltaic cells, and thermal management devices based on Seebeck effect. Thermal management devices using InGaAs can have enhanced Seebeck coefficients and reduced cross-plane thermal conductivity. Without being bound by any particular theory or mode of operation, the Seebeck coefficient (also known as thermopower, thermoelectric power, and thermoelectric sensitivity) of a material is a measure of the magnitude of an induced thermoelectric voltage in response to a temperature difference across that material, as induced by the Seebeck effect. The SI unit of the Seebeck coefficient is volts per kelvin (V/K). Alternatively, the Seebeck coefficient can be given in microvolts per kelvin (μV/K).

In yet another example, the epitaxial layer 130 includes GaN, which can be used to fabricate semiconductor lasers (e.g., violet laser diode), LEDs (e.g., from red to ultraviolet (UV), based on InGaN or AlGaN), transistors (e.g., MOSFETs, MESFETs, and HEMTs), and piezoelectric devices (e.g., micro-motors, sensors, and actuators). Other materials that can be grown in the epitaxial layer 130 can include, for example, Bi₂Se₃ (e.g., for energy harvesting based on the Seebeck effect), Bi₂Te₃ (e.g., for thermal management or microelectronic cooling), Sb₂Se₃, Sb₂Te₃, SiGe (e.g., for energy harvesting), BaTiO₃ (e.g., for ferroelectric sensors), SrTiO₃ (e.g., for actuators, micrometer, and memory), and GeSbTe (e.g., for memory).

Methods of Fabricating Semiconductor Devices Using Organic Release Layers

FIGS. 2A-2B illustrate a method 200 of fabricating semiconductor devices using an organic release layer 220. In this method 200, the organic release layer 220 is formed on a growth substrate 210, as shown in FIG. 2A. The organic release layer 220 is made of planar organic molecules, which can form an ordered planar layer on the growth substrate 210. The organic release layer 220 can be about one molecule thick (i.e., it can be a monolayer of organic molecules) to facilitate remote epitaxy.

In FIG. 2B, an epitaxial layer 230 is fabricated on the organic release layer 220. The fabrication can include epitaxial growth seeded by the growth substrate 210. The epitaxial layer 230 can include a single-crystalline film made of any of the materials described herein (e.g., InP, GaAs, or InGaAs, etc.).

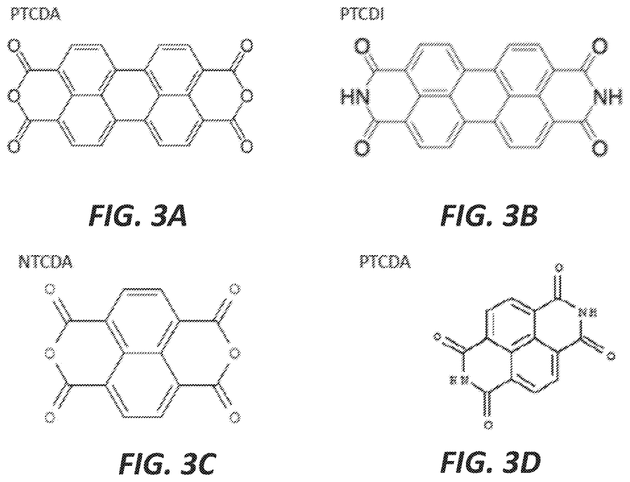

The planar organic molecules in the organic release layer 220 can include any appropriate organic molecule in which the constituent atoms of the organic molecules are on the same plane. FIGS. 3A-3D show molecular structures of several planar organic molecules that can be used in the release layer 220. FIG. 3A shows the molecular structure of perylenetetracarboxylic dianhydride (PTCDA). FIG. 3B shows a molecular structure of N, N′-Dioctyl-3,4,9,10 perylenedicarboximide (PTCDI-C8). FIG. 3C shows the molecular structure of 1,4,5,8-naphthalene-tetracarboxylic-dianhydride (NTCDA). FIG. 3D shows the molecular structure of naphthalenetetracarboxylic diimide (NTCDI).

The planar organic molecules in the release layer 220 can have a relatively small molecular weight. For example, the molecular weight of the planar organic molecule can be substantially equal to or less than 500 g/mol (e.g., about 500 g/mol, about 450 g/mol, about 400 g/mol, about 350 g/mol, about 300 g/mol, or less, including any values and sub ranges in between). Larger molecular weights can also be used. In addition, the remote epitaxy can also benefit from a thin release layer 220. For example, the thickness of the organic release layer 220 can be substantially equal to or less than 2 nm (e.g., about 2 nm, about 1.8 nm, about 1.6 nm, about 1.4 nm, about 1.2 nm, about 1 nm, or less, including any values and sub ranges in between).

The release layer 220 can be fabricated directly on the growth substrate 210 via, for example, evaporation (e.g., physical evaporation deposition, or PVD, or thermal evaporation). During evaporation, the planar organic molecules undergo quasi-epitaxial growth on a semiconductor substrate, such as a silicon or GaAs substrate. The planar organic molecules form an ordered planar layer on the substrate due to a molecule-molecule interaction that is stronger than the molecule-substrate interaction.

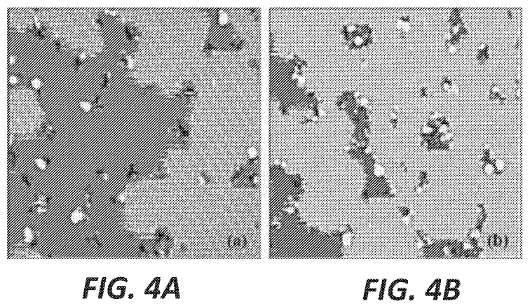

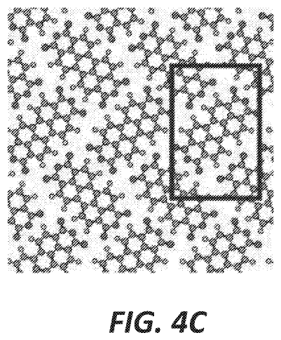

FIGS. 4A-4C illustrate the formation of an ordered planar layer of PTCDA on a Pb/Si substrate. FIGS. 4A and 4B are scanning electron microscopy (SEM) images of PTCDA molecules grown on the Pb/Si substrate with different surface coverages. They demonstrate that PTCDA can form monolayer (i.e., 2D layer) instead of a 3D structure. FIG. 4C shows a schematic of the molecular structure of PTCDA grown on the Pb/Si substrate. More details about growth of ordered molecular layers of PTCDA can be found in Nicoara N Mendez J, and Gómez-Rodríguez J M., “Growth of ordered molecular layers of PTCDA on Pb/Si(111) surfaces: a scanning tunneling microscopy study,” Nanotechnology, 27(36):365706, (2016), which is hereby incorporated herein by reference in its entirety.

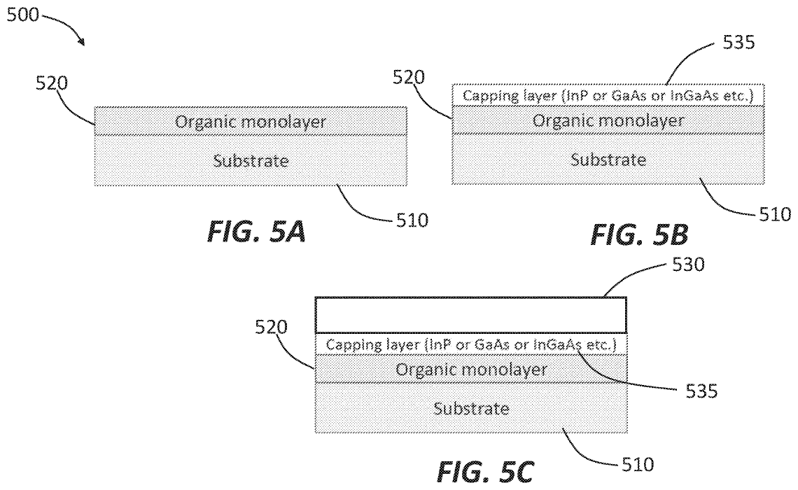

FIGS. 5A-5C illustrate a method 500 of fabricating a semiconductor device using a capping layer 535 to protect an organic release layer 520. The capping layer 535 protects the organic release layer 520 from possible damage caused by, for example, high temperature during epitaxial growth of the epitaxial layer 530. The method 500 starts with the release layer 520 disposed on a growth substrate 510, as illustrated in FIG. 5A. The release layer 520 can be substantially identical to the release layer 220 shown in FIGS. 2A-2B. The capping layer 535 is formed on the release layer 520 (FIG. 5B), followed by the epitaxial growth of an epitaxial layer 530 (FIG. 5C). The capping layer 535 and the epitaxial layer 530 can include the same material (e.g., InP, GaAs, InGaAs, etc.). However, the fabrication of the capping layer 535 is conducted at a temperature lower than the temperature for the epitaxial growth of the epitaxial layer 530. For example, the epitaxially growth can be conducted at 480° C. (e.g., for InP), 580° C. (e.g., for GaAs), or higher, while the capping layer 535 can be fabricated at 400° C. or lower.

The thickness of the capping layer 535 depends on at least two factors. On one hand, a thicker capping layer 535 can provide better protection for the release layer 520. On the other hand, a thinner capping layer 535 can be beneficial to remote epitaxy, i.e., epitaxial growth of the epitaxial layer 530 seeded by the growth substrate 510. Based on these considerations, the capping layer 525 can be about 1 atom thick to about 10 atoms thick, i.e., the capping layer 535 includes about 1 atom to about 10 atoms across its thickness. For example, the thickness of the capping layer 535 can be about 2 nm to about 10 nm (e.g., about 2 nm, about 3 nm, about 4 nm, about 5 nm, about 6 nm, about 7 nm, about 8 nm, about 9 nm, or about 10 nm, including any values and sub ranges in between).

Transferring an Epitaxial Layer from an Organic Release Layer

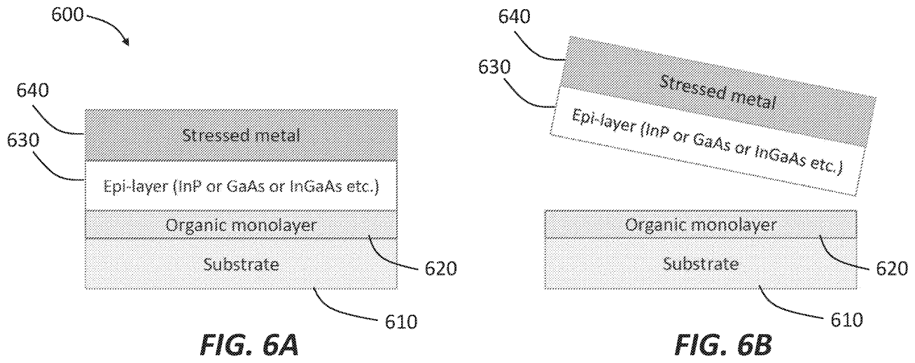

FIGS. 6A and 6B illustrate a method 600 of transferring an epitaxial layer fabricated using the method 200 illustrated in FIGS. 2A-2B. In the method 600, a stressor 640 is formed on an epitaxial layer 630, which is epitaxially grown on an organic release layer 620 and seeded by a growth substrate 610 disposed underneath the release layer 620. The stressor 640 can be substantially identical to the stressor 140 shown in FIGS. 1A-1D and described above. An optional tape layer can be disposed on the stressor 640 to facilitate handling of the stressor 640 and the epitaxial layer 630. The tape and the stressor 640 can be used to mechanically exfoliate the epitaxial layer 630 from the release layer 620 by applying high strain energy to the interface between the epitaxial layer 630 and the release layer 620, as illustrated in FIG. 6B. The released epitaxial layer 630 can be transferred to a host substrate for further processing.

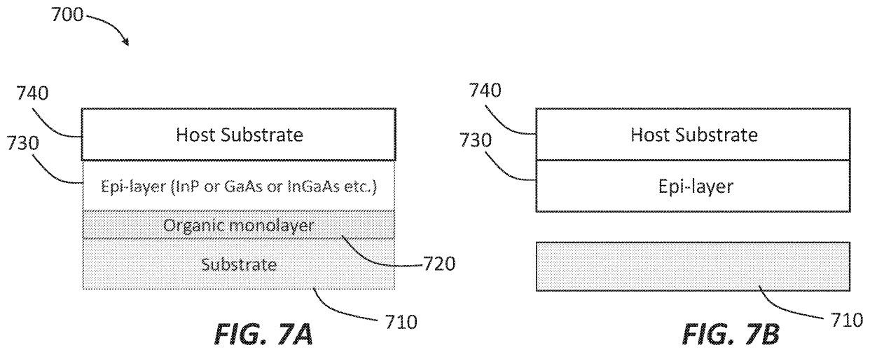

FIGS. 7A and 7B illustrate a method 700 of transferring an epitaxial layer by etching away the organic release layer. FIG. 7A shows that a second substrate 740 is formed on an epitaxial layer 630, which is epitaxially grown on an organic release layer 720 using a growth substrate 710 as the seed. In FIG. 7B, the organic release layer 720 is etched away (e.g., using acetone), resulting in a freestanding epitaxial layer 730 attached to the second substrate 740. In one example, the second substrate 740 can function as a handle to, for example, transfer the epitaxial layer 730 to a target substrate (also referred to as a host substrate) for further processing. In another example, the second substrate 740 can be the target substrate, and after the etching of the organic release layer 720, the epitaxial layer 730 is ready for further processing.

In the method 700, since the organic release layer 720 is etched away when transferring the epitaxial layer 730 away from the growth substrate 710, a new release layer can be formed on the growth substrate 710 for the next cycle of epitaxial growth. As described herein, the organic release layer 720 can be conveniently fabricated via evaporation techniques. Therefore, the formation of the release layer 720 for each epitaxial growth impose

Methods of Fabricating Semiconductor Devices Using a Sacrificial Layer

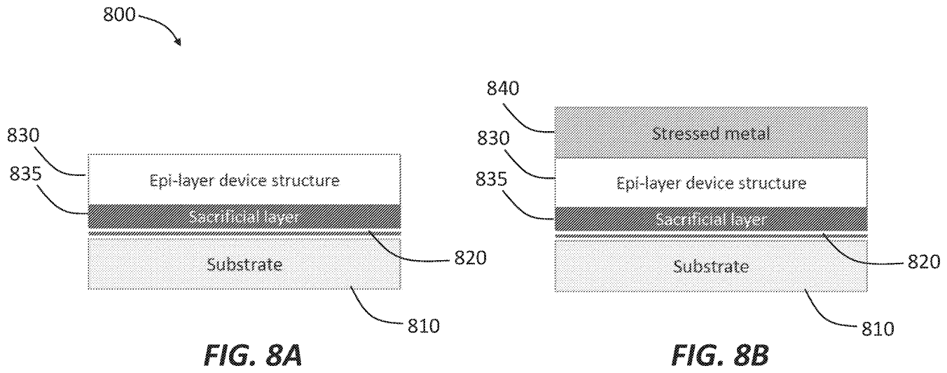

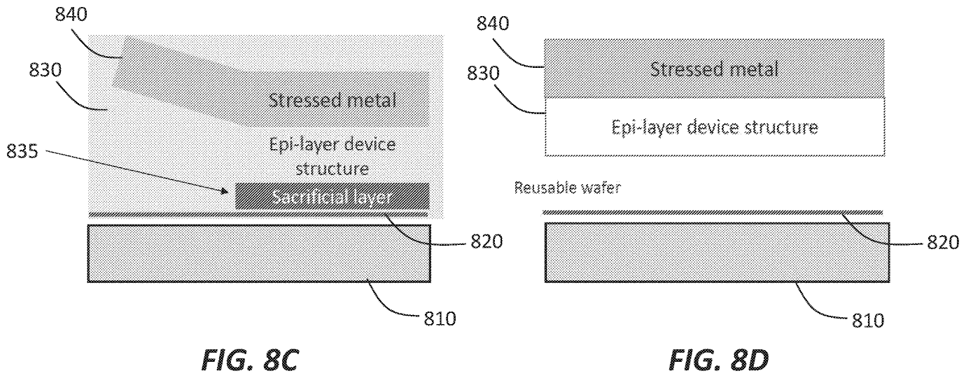

FIGS. 8A-8D illustrate a method 800 of fabricating semiconductor devices using a sacrificial layer 835 in combination with a release layer 820. In this method 800, an epitaxial layer 830 is epitaxially grown on the sacrificial layer 835, which is disposed on the release layer 820. A growth substrate 810 is disposed underneath the release layer 820 to seed the growth of the epitaxial layer 830, as shown in FIG. 8A. In FIG. 8B, a stressor 840 is formed on the epitaxial layer 830. In FIG. 8C, the sacrificial layer 835 is selectively etched away (i.e., with little to no etching of the epitaxial layer 830 or the release layer 820), leaving a freestanding epitaxial layer 830 attached to the stressor 840 (FIG. 8D) for further processing. In the method 800, selective etching of the sacrificial layer 835 can more precisely release the epitaxial layer 830 at the interface of the release layer 820.

In one example, the sacrificial layer 835 includes GaAs, and the epitaxial layer 830 includes AlAs or AlGaAs. In this case, the sacrificial layer 835 can be etched away using HF. In another example, the sacrificial layer 835 includes GaAs, and the epitaxial layer 830 includes AlInP, GaInP, or AlGaInP, in which case the etching solution can be HCl. In yet another example, the sacrificial layer 835 can include InP, and the epitaxial layer 830 can include InGaAs, thereby allowing selective etching of the sacrificial layer 835 using HCl. In yet another example, the sacrificial layer 835 includes InP, the epitaxial layer 830 includes AlAs or AlGaAs, and HF can be used to selectively etching away the sacrificial layer 835.

The sacrificial layer 835 can be at least 2 atoms thick to facilitate the etching shown in FIG. 8C. For example, the thickness of the sacrificial layer 835 can be about 10 nm to about 100 nm (e.g., about 10 nm, about 20 nm, about 30 nm, about 50 nm, about 75 nm, or about 100 nm, including any values and sub ranges in between).

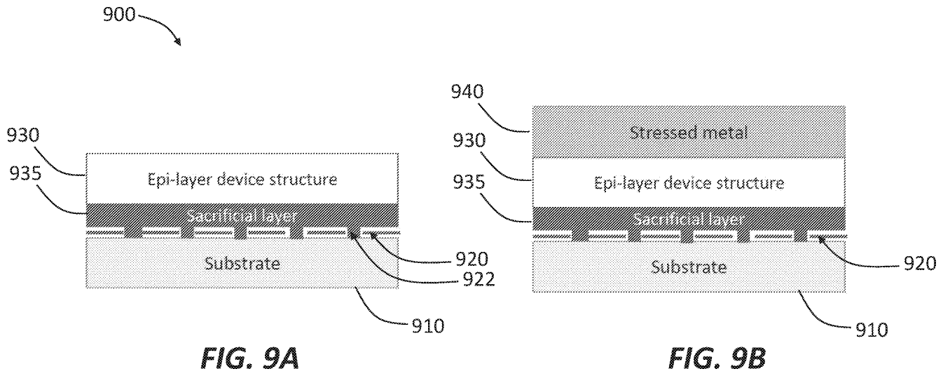

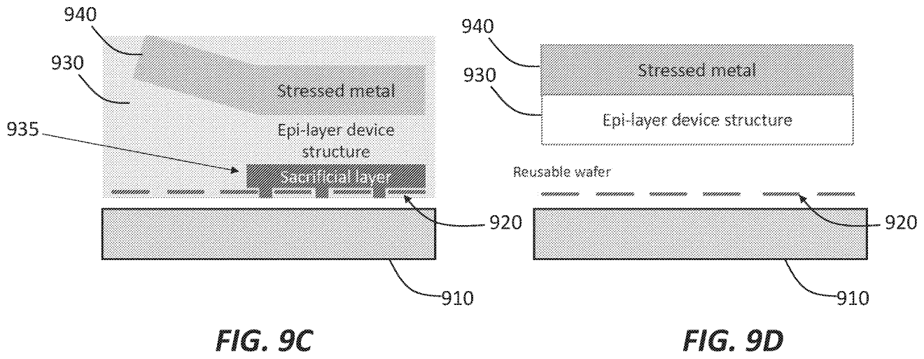

FIGS. 9A-9D illustrate a method 900 of fabricating semiconductor devices using a patterned release layer 920 in combination with a sacrificial layer 935. In this method 900, an epitaxial layer 930 is grown on the patterned release layer 920 that is disposed on the sacrificial layer 935. The growth of the epitaxial layer 930 is seeded by a growth substrate 910 disposed underneath the patterned release layer 920. In FIG. 9B, a stressor 940 is formed on the epitaxial layer 930. In FIG. 9C, the sacrificial layer 935 is selectively etched away, leaving a freestanding epitaxial layer 930 attached to the stressor 940 (FIG. 8D) for further processing. The platform including the patterned release layer 920 disposed on the growth substrate 910 can then be used for next cycle of epitaxial growth (including the formation of another sacrificial layer).

The patterned release layer 920 used in the method 900 can be substantially identical to any release layer described herein except that the patterned release layer 920 is patterned with pinholes 922 that can facilitate remote epitaxy through the release layer 920. The density of pinholes 922 in the patterned release layer 920 can be, for example, about one pinhole 922 per square micron or higher. The pinholes 922 may be distributed across the patterned release layer 920 randomly or in a periodic array. The pinholes 922 can be created using, for example, Ar plasma or O₂ plasma.

The epitaxial growth of the epitaxial layer 930 can start from the area where the pinholes 922 are created in the patterned release layer 920. The pinholes 922 allow direct interaction of the growth substrate 910 with the epitaxial layer 930, thereby allowing the growth substrate 910 to guide the crystalline orientation of the epitaxial layer 930. Put differently, the epitaxial layer 930 may grow through the pinholes 922. The growth of the epitaxial layer 930 can then extend to cover the entire release layer 920, then released using one of the techniques described above. Because the pinholes 922 have small diameters, the epitaxially grown material connecting the epitaxial layer 930 with the growth substrate 910 is relatively weak, so it does not hinder release of the epitaxial layer 930 from the patterned release layer 920.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of” “only one of” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of manufacturing a semiconductor device, the method comprising:
forming a release layer on a first substrate, the release layer comprising a planar organic molecule;
forming a single-crystalline film on the release layer; and
transferring the single-crystalline film from the release layer to a second substrate.

2. The method of claim 0, wherein the planar organic molecular has a molecular weight substantially equal to or less than 500 g/mol.

3. The method of claim 0, wherein the planar organic molecule comprises at least one of:
perylenetetracarboxylic dianhydride (PTCDA),
1,4,5,8-naphthalene-tetracarboxylic-dianhydride (NTCDA), or
N,N′-Dioctyl-3,4,9,10 perylenedicarboximide (PTCDI-C8).

4. The method of claim 0, wherein forming the release layer comprises depositing the release layer on the first substrate via evaporation.

5. The method of claim 0, wherein the release layer has a thickness substantially equal to or less than 2 nm.

6. The method of claim 0, wherein forming the single-crystalline film comprises epitaxially growing the single-crystalline film using the first substrate as a growth seed.

7. The method of claim 0, further comprising:
forming a capping layer on the release layer before forming the single-crystalline film.

8. The method of claim 0, wherein forming the capping layer comprises depositing the capping layer on the release layer at a first temperature, and forming the single-crystalline film comprises epitaxially growing the single-crystalline layer on the capping layer at a second temperature greater than the first temperature.

9. The method of claim 0, wherein the capping layer has a thickness of about 2 nm to about 10 nm.

10. The method of claim 0, wherein transferring the single-crystalline film comprises:
forming a metal stressor on the single-crystalline film;
disposing a flexible tape on the metal stressor; and
pulling the single-crystalline film and the metal stressor off the release layer with the flexible tape.

11. The method of claim 0, further comprising:
forming another single-crystalline film on the release layer after transferring the single-crystalline film to the second substrate.

12. The method of claim 0, wherein transferring the single-crystalline film comprises etching away the release layer so as to remove the single-crystalline layer from the first substrate.

13. The method of claim 0, further comprising:
forming another release layer on the first substrate; and
forming another single-crystalline layer on the another release layer.

14. A semiconductor device formed by the method of claim 0.

15. A method of manufacturing a semiconductor device, the method comprising:
depositing, via evaporation, a planar organic molecule on a first substrate to form a release layer having a thickness substantially equal to or less than 2 nm;
forming a first capping layer on the release layer at a first temperature, the first capping layer comprising a semiconductor and having a thickness of about 5 nm to about 10 nm;
epitaxially growing a first single-crystalline film on the first capping layer at a second temperature greater than the first temperature, the first single-crystalline film comprising the semiconductor;
transferring the first single-crystalline film from the release layer to a second substrate;
forming a second capping layer on the release layer; and
forming a second single-crystalline film on the second capping layer.

16. A method of semiconductor processing, the method comprising:
forming a release layer on a first substrate;
forming a sacrificial layer on the release layer;
forming a single-crystalline film on the release layer;
etching away the sacrificial layer so as to release the single-crystalline film from the first substrate; and
transferring the single-crystalline film from the first substrate to a second substrate.

17. The method of claim 0, wherein the release layer has a thickness substantially equal to or less than 2 nm.

18. The method of claim 0, wherein the release layer comprises a two-dimensional (2D) material.

19. The method of claim 0, wherein the sacrificial layer comprises a first semiconductor and the single-crystalline film comprises a second semiconductor lattice matched to the first semiconductor.

20. The method of claim 0, wherein the sacrificial layer comprises GaAs, the single-crystalline film comprises at least one of AlAs or AlGaAs, and etching away the sacrificial layer comprises etching away the sacrificial layer using HF.

21-27. (canceled)
